(19) United States
(12) Patent Application Publication
(10) Pub. No.: US 2026/0362623 A1
(43) Pub. Date: Nov. 12, 2026

(54) POWER MODULE, ELECTRICAL DEVICE AND METHOD FOR PRODUCING A POWER MODULE

(71) Applicant: SIEMENS AKTIENGESELLSCHAFT, München (DE)

(72) Inventor: Ewgenij Ochs, Puschendorf (DE)

(21) Appl. No.: 19/100,293

(22) PCT Filed: Jun. 19, 2023
(86) PCT No.: PCT/EP2023/066370

§ 371 Date: Jan. 31, 2025

(30) Foreign Application Priority Data
Aug. 3, 2022 (EP) 22188441.4

(51) Int. Cl. H05K 7/14; H01G 2/14; H02M 7/00

(52) U.S. Cl. CPC H05K 7/1432; H02M 7/003; H01G 2/14

(57) ABSTRACT

The invention relates, inter alia, to a power module (1) having an AC connection side (2) and a DC connection side (3) opposite from the AC connection side (2), the power module (1) also comprising:—a printed circuit board (4),—at least one alternating voltage terminal (AC) disposed on the AC connection side (2), and—at least three direct voltage terminals (DCP, DCM, DCN) including one or more middle direct voltage terminals (DCM) and two outer direct voltage terminals (DCP, DCN) including a positive direct voltage terminal (DCP) and a negative direct voltage terminal (DCN), wherein one of the middle direct voltage terminals (DCM) and one of the outer direct voltage terminals (DCP, DCN) are disposed on the DC connection side (3) and, in a plan view, outside of the printed circuit board (4). In order, inter alia, to provide an improved power module (1), it is proposed, inter alia, that the remaining of the direct voltage terminals (DCP, DCM, DCN) is disposed between the AC connection side (2) and the DC connection side (3) and, in a top view, in the region of the printed circuit board (4), in particular in the region of a transistor module (20) of the power module (1).

### CROSS REFERENCE TO RELATED APPLICATIONS

The present patent document is a § 371 nationalization of PCT Application Serial Number PCT/EP2023/066370, filed Jun. 19, 2023, designating the United States which is hereby incorporated in its entirety by reference. This patent document also claims the benefit of EP22188441.4 filed on Aug. 3, 2022, which is hereby incorporated in its entirety by reference.

### FIELD

Embodiments relate to a power module having an AC terminal side and a DC terminal side opposite the AC terminal side, the power module also including a printed circuit board, at least one alternating voltage terminal disposed on the AC terminal side and at least three direct voltage terminals including one or more middle direct voltage terminals and two outer direct voltage terminals including a positive direct voltage terminal and a negative direct voltage terminal. One of the middle direct voltage terminals and one of the outer direct voltage terminals are disposed on the DC terminal side and, in a plan view, outside of the printed circuit board.

### BACKGROUND

Apparatuses or methods are employed in a plurality of applications in power electronics. In power electronics for example, semiconductor components, for better handling, are used in housings, for example Insulated-Gate Bipolar Transistor (IGBT) modules, with external terminal technology. For lower powers the connections are routed out of the housing, often called a package, as pads. For higher powers, screw terminals are used with larger contact surfaces in order to connect further connections, such as for example internal busbars, to the terminals. Like all other components in power electronics, high demands are also made on the IGBT modules. Embodiments are able to be applied for example to screw terminal technology of the IGBT modules for higher power, for example the “EconoDual3” IGBT modules from Infineon Technologies AG, Munich, “SEMiX” from SEMIKRON Elektronik GmbH & Co. KG, Nuremberg or “SD3” from Siemens AG, Munich.

These above-mentioned IGBT modules are used specifically for applications in 2-level technology, in order for example to realize an individual half bridge made of a number of individual IGBT semiconductors.

A power semiconductor module with four power terminals is known from U.S. Pat. No. 8,847,328B1. An IGBT includes a collector, that is connected to the first power terminal, and an emitter, that is coupled to the third power terminal. An antiparallel diode is coupled in parallel with the IGBT. A DC link is connected between the second and the fourth power terminal. The DC link may include two diodes and two IGBTs. The IGBTs are connected in a configuration with a common collector. The first and second power terminals are disposed in a first line along one side of the module, and the third and fourth power terminals are disposed in a second line along the opposite side of the module. Two identical entities of the module may be connected to one another in order to form a three-stage NPC phase branch with low stray inductance. The phase branch includes two parallel DC link connections.

### BRIEF DESCRIPTION AND SUMMARY

The scope of the embodiments is defined solely by the appended claims and is not affected to any degree by the statements within this summary. The present embodiments may obviate one or more of the drawbacks or limitations in the related art. Independent of the grammatical term usage, individuals with male, female or other gender identities are included within the term.

Embodiments provide an improved power module and a corresponding electrical device, that for example makes possible a low-inductance terminal technology.

Embodiments provide a power module having an AC terminal side and a DC terminal side opposite the AC terminal side, the power module also including a printed circuit board, at least one alternating voltage terminal disposed on the AC terminal side and at least three direct voltage terminals including one or more middle direct voltage terminals and two outer direct voltage terminals including a positive direct voltage terminal and a negative direct voltage terminal. One of the middle direct voltage terminals and one of the outer direct voltage terminals are disposed on the DC terminal side and, in a plan view, outside of the printed circuit board. The respective remaining terminals of the direct voltage terminals are disposed between the AC terminal side and the DC terminal side and, in a plan view, in the region of the printed circuit board, for example in the region of a transistor module of the power module.

Embodiments further provide an electrical device including at least one such power module.

Embodiments further provide a method for producing the power module by the following method steps: provision of an initial power module having: at least one alternating current terminal disposed on the AC terminal side and two direct current terminals disposed on the DC terminal side, provision of the printed circuit board between the AC terminal side and the DC terminal side in such a way that one of the middle direct current terminals and one of the outer direct current terminals are disposed on the DC terminal side in each case and, in a plan view, are disposed outside the printed circuit board, and provision of the at least one further direct current terminal between the AC terminal side and the DC terminal side and, in a plan view, in the region of the printed circuit board, for example in the region of a transistor module of the power module.

The power module includes a printed circuit board, that is, for example, electrically connected to each of the direct current terminals and also to each of the alternating current terminals. The power module may be supplied on one side, the AC terminal side, with an AC voltage and on the opposite side, the DC terminal side, with a DC voltage. For example the printed circuit board may convert the AC voltage that is able to be supplied to the power module via the alternating current terminal or the alternating current terminals into corresponding DC voltages, that the power module may make available via the direct current terminals. Conversely the printed circuit board may for example convert the DC voltages, that are able to be supplied to the power module via the direct current terminals, into a corresponding AC voltage, that the power module may make available via the alternating current terminal or the alternating current terminals. For the voltage conversion mentioned, the power module may have at least one semiconductor component or a power semiconductor for example, i.e. for example components that are based for example on silicon, gallium nitride or silicon carbide and that are configured in power electronics for control and switching of high electrical currents and voltages, i.e. for example currents of more than 1 ampere and voltages of more than around 24 volts. Examples of such components are power diodes, thyristors, triacs and transistors, such as for example power MOSFETs, IGBTs and the like. Furthermore the power module may have an electrical resistor, for example a measurement resistor. For example the power module includes one transistor, for example at least two transistors. At least one of the transistors may be disposed in each case between two of the direct current terminals. The transistor or the transistors may be part of a transistor module of the power module.

At least one alternating current terminal is provided on the AC terminal side of the power module. Often two such alternating current terminals are present, that are usually supplied with the same AC voltage. Two direct current terminals are provided on the DC terminal side of the power module, for example one of the outer direct current terminals and the middle direct current terminal or one of the middle direct current terminals. The remaining direct current terminal or the remaining direct current terminals is or are disposed between the AC terminal side and the DC terminal side. The remaining direct current terminal or the remaining direct current terminals is or are still disposed, in a plan view, in the region of the printed circuit board. In a plan view the printed circuit board is thus at least partly covered by the remaining direct current terminal or the remaining direct current terminals. While for example the respective alternating current terminal or the two direct current terminals disposed on the DC terminal side may essentially be disposed in the plane of the printed circuit board in an extension of the printed circuit board to the AC terminal side or to the DC terminal side, the respective remainder of the direct current terminals are disposed above the printed circuit board.

The power module may for example have one or more transistor modules, especially IGBT modules. The respective transistor module includes a transistor and where necessary further elements, such as for example electrical terminals, a transistor module housing or a transistor module heatsink. The respective transistor module may be disposed on the printed circuit board, for example on the rear side of the printed circuit board, when the remaining direct current terminal or the remaining direct current terminals is or are disposed on the front side of the printed circuit board. For example the respective remaining direct current terminal is disposed, in a plan view, in the region of the respective transistor module. Thus, in a plan view first of all the respective remaining direct current terminal, then the printed circuit board and then the respective transistor module may be disposed. For example the respective transistor module is electrically connected to the printed circuit board and to the respective remaining direct current terminal. This embodiment of the power module provides an especially low inductance structure to be achieved.

For example the power module may be configured in a cube shape. The AC terminal side and the DC terminal side lie opposite one another (for example as the upper side and the lower side of the cube). The remaining direct current terminal or the remaining direct current terminals may then be disposed on one of the side surfaces of the cube for example. The power module may in some examples have approximately the shape of a domino, that are comparatively long and thin and have a comparatively large base surface. In such examples the AC terminal side and the DC terminal side may be disposed for example on the two smallest side surfaces. The remaining direct current terminal or the remaining direct current terminals may then for example be disposed on the two medium-sized side surfaces. The power module formed in this way lies for example on its base surface (i.e. one of its two largest side surfaces) on a heatsink.

The power module may for example further have precisely three direct current terminals, for example a positive direct current terminal, a middle direct current terminal and a negative direct current terminal. In this example the positive direct current terminal and the middle direct current terminal are disposed on the DC terminal side and the negative direct current terminal is disposed between the AC terminal side and the DC terminal side and, in a plan view, in the region of the printed circuit board or of the respective transistor module. As an alternative the negative direct current terminal and the middle direct current terminal may be disposed on the DC terminal side and the positive direct current terminal is disposed between the AC terminal side and the DC terminal side and, in a plan view, in the region of the printed circuit board or of the respective transistor module, so that the negative direct current terminal and the positive direct current terminal are swapped. When the power module includes precisely three direct current terminals, 3-level applications are able to be realized, that indeed have three different DC voltage potentials.

What is more, the power module may also have four or more direct current terminals, for example a positive direct current terminal, two or more middle direct current terminals and a negative direct current terminal. In this example the positive direct current terminal and one of the middle direct current terminals are disposed on the DC terminal side. The negative direct current terminal and also the remaining middle direct current terminal or the remaining middle direct current terminals are disposed between the AC terminal side and the DC terminal side and, in a plan view, in the region of the printed circuit board or of the respective transistor module. When the power module includes precisely four or more direct current terminals, applications with 4 or more levels or DC voltage potentials are able to be realized.

Of particular advantage with the power module in such cases is that a low-inductance structure may be realized. This is especially achieved by the two outer direct current terminals being disposed comparatively close to one another. For example the direct current terminals DCP, DCM, DCN, for a use of the power module in a 3-level converter are disposed as DC link connections DCP-DCM-DCN close to one another, that for example contributes to a significant improvement in the switching behavior of the power switches present in the converter or in the power module and thus to markedly reducing the power losses of power semiconductors.

Furthermore the power module may have a housing, that houses the printed circuit board and where necessary at least partly houses further elements of the power module.

The direct current terminals and the alternating current terminals may each be configured as a screw terminal for example.

In an embodiment the respective middle direct current terminal is disposed between the positive direct current terminal and the negative direct current terminal.

Especially good results as regards the low-inductance structure may be realized by the respective middle direct current terminal being disposed between the two outer direct current terminals. For example, in a plan view of the power module, first of all the negative direct current terminal, then the middle direct current terminal or the middle direct current terminals, and finally the positive direct current terminal are disposed in the clockwise direction or in the counterclockwise direction.

When more than one middle direct current terminal is present then the middle direct current terminals are for example disposed in accordance with their respective electrical potential provided, in ascending order from the negative direct current terminal to the positive direct current terminal or in descending order from the positive direct current terminal to the negative direct current terminal.

For example the direct current terminals are each essentially disposed equidistant from one another. For a power module with three direct current terminals the middle direct current terminal is thus essentially at the same distance from the positive direct current terminal as from the negative direct current terminal. This means that the middle direct current terminal is essentially disposed in the middle between the positive direct current terminal and the negative direct current terminal. In such cases deviations from the equidistance of for example ±20% or ±10% may still be acceptable.

In an embodiment of the power module, the two outer direct current terminals are disposed comparatively close to one another. The middle direct current terminal or the middle direct current terminals is or are disposed in the middle. Thus the switching behavior of the power switches that may be present in the converter or in the power module may be further improved and thus the power losses of power semiconductors may be further reduced.

In an embodiment the printed circuit board includes at least one terminal pin protruding from the printed circuit board between the AC terminal side and the DC terminal side. The remaining of the respective direct current terminals is connected electrically to the respective terminal pin.

For example the respective terminal pin protrudes from the plane of the flatter printed circuit board at right angles and is disposed between the AC terminal side and the DC terminal side. Thus the remainder of the respective direct current terminals, in a plan view, may be disposed in the region of the printed circuit board or of the respective transistor module, by the respective remainder of the direct current terminals being electrically connected to the respective terminal pin. In a few examples in such cases two or more terminal pins may also be provided per remaining direct current terminal, whereby higher currents may be made possible. Furthermore, two or more of the remaining direct current terminals may be provided, that are connected via one or more respective terminal pins to the printed circuit board. Through this embodiment of the power module the applications already mentioned above with 4 or more levels or DC voltage potentials are able to be realized.

For example the respective terminal pin may be a terminal pin of a transistor or of the above-mentioned transistor module, that is disposed on the printed circuit board or on the rear side of the printed circuit board.

In an embodiment the power module furthermore includes a respective conductor surface. The respective conductor surface is disposed between the respective terminal pin and the respective remainder of the direct current terminals. The respective terminal pin and the respective remainder of the direct current terminals is electrically connected to the respective conductor surface.

The respective conductor surface may for example be equipped as a flat board of an electrically conducting material, for example copper or aluminum, or also as DCB (Direct Copper Bonded), and is electrically connected to the respective terminal pin and to the respective remainder of the direct current terminals. Through the respective conductor surface the electrical connection of the respective terminal pin to the respective remainder of the direct current terminals is facilitated and in addition is configured mechanically more robustly. With two or more of the remaining direct current terminals at least one conductor surface is provided per remaining direct current terminal.

The respective conductor surface, apart from being attached via the respective terminal pin, may for example additionally be attached to the printed circuit board and/or to a housing of the power module that may possibly be present.

In an embodiment the respective conductor surface is disposed in parallel to the printed circuit board. As an alternative or in addition, the printed circuit board, in a plan view, completely covers the respective conductor surface.

The arrangement of the respective conductor surface parallel to the printed circuit board produces a compact and stable structure, that furthermore supports a low-inductance terminal technology. A compact structure is also supported by the printed circuit board completely covering the respective conductor surface. For example the respective terminal pin, in a plan view, is covered on the printed circuit board by the respective conductor surface.

In an embodiment the power module furthermore includes at least two capacitors. One of the capacitors is electrically connected to one of the outer direct current terminals and to one of the middle direct current terminals. Another of the capacitors is electrically connected to the other of the outer direct current terminals and to one of the middle direct current terminals. The electrical connection between the respective capacitor and the respective direct current terminal is at most twice as long, especially at most exactly the same length or at most half as long as the distance between the two outer direct current terminals.

In an embodiment of the power module with three direct current terminals, i.e. suitable for 3-level applications, at least two capacitors are provided. The one capacitor is electrically connected to the positive direct current terminal and to the middle direct current terminal and the other capacitor to the middle direct current terminal and to the negative direct current terminal. Correspondingly, in an embodiment of the power module with four or more direct current terminals, i.e. suitable for applications with 4 or more levels or DC voltage potentials, at least three or correspondingly more capacitors are provided. The one capacitor is electrically connected to the positive direct current terminal and to the middle direct current terminal of the second-largest electrical potential. The next capacitor is electrically connected to the middle direct current terminals of the second-largest electrical potential and of the third-largest electrical potential, etc., until finally the last capacitor is electrically connected to the middle direct current terminal of the second-lowest electrical potential and to the negative direct current terminal. In principle two or more capacitors may also be disposed in series or in parallel to one another between the pairs of direct current terminals.

An especially low-inductance structure is able to be achieved by the electrical connection between the respective capacitor and the respective direct current terminal being configured as short as possible, advantageously at most twice as long, especially at most exactly the same length or at most half as long as the distance between the two outer direct current terminals. In a few examples the connection may also be at most twice as long, especially at most exactly the same length or at most half as long as the distance between the direct current terminals of the respective the pairs of direct current terminals.

In an embodiment the power module furthermore includes a capacitor board, on which the respective capacitor is disposed. The capacitor board is for example disposed parallel to the printed circuit board, and the respective capacitor is disposed on the capacitor board, especially within a rectangle, that, in a plan view, is delimited by the direct current terminals and that is aligned in parallel to the printed circuit board.

For example the capacitor board may be configured as a further printed circuit board. The capacitors are disposed on the capacitor board. The capacitors are electrically connected as described above to the direct current terminals. A simple and likewise robust structure of the power module may especially be achieved by the capacitor board being disposed parallel to the printed circuit board and by the capacitor board for example being located on the upper side of the printed circuit board. Furthermore a compact and particularly low-inductance structure of the power module may be achieved by the capacitor board being disposed in the region of the direct current terminals or of the respective transistor module, so that the respective capacitor is likewise disposed in the vicinity or in the region of the direct current terminals. Usually the direct current terminals are disposed in such a way that, in a plan view of the printed circuit board, they delimit a rectangle or may be enclosed by a rectangle. For example the smallest possible such rectangle is considered. For example the respective capacitor is then disposed on the capacitor board within this rectangle, whereby short electrical connection paths between the respective direct current terminal and the respective capacitor and thus overall a lower-inductance structure of the power module are able to be realized.

In some examples the electrical connection between the respective capacitor and the respective direct current terminal is at most twice as long, especially at most exactly the same length or at most half as long as the distance between the two outer direct current terminals.

For example at least half of the capacitors of the power module, for example three quarters or all of the capacitors of the power module are disposed in the rectangle or are electrically connected via the electrical connection to the respective direct current terminal.

The capacitor board may for example be attached to the printed circuit board and/or to any housing of the power module that might be present.

In an embodiment the power module furthermore includes a respective busbar, that is electrically connected to the respective direct current terminal and optionally to the respective capacitor. The busbars are at least predominantly disposed in parallel to one another. The respective busbar of the respective middle direct current terminal is disposed between the busbars of the two outer direct current terminals.

Thus one busbar may be provided in each case per direct current terminal. The busbars are routed for at least half of their length in parallel to one another. For example the vast majority of the busbars, for example at least for three quarters or 90% of their length, are routed parallel to one another. For example the busbars may be disposed equidistant from one another in this case, i.e. for a power module with the busbars, by the busbar of the middle electrical potential being disposed in the middle between the busbars of the negative and the positive electrical potential, wherein deviations of ±5% to ±10% may still be acceptable and wherein the equidistant arrangement of the busbars may be provided over the length stated above, i.e. at least 50%, 75% or 90% of the length of the busbars. If more than one middle direct current terminal is present, two neighboring busbars thus for example each have the same distance between them. The equidistance may likewise have the deviations or be present over the length. The parallel or equidistant routing of the busbars contributes to a low-inductance structure of the power module.

The low-inductance structure of the power module is furthermore supported by the busbar of the middle direct current terminal or the busbars of the middle direct current terminals being disposed between the busbars of the two outer direct current terminals. If more than one middle direct current terminal is present, the busbars of the middle direct current terminals are for example disposed in accordance with their respective electrical potential provided, in ascending order from the negative direct current terminal to the positive direct current terminal or in descending order from the positive direct current terminal to the negative direct current terminal.

The respective busbar may furthermore have a rectangular cross section. The long side or the short side of the rectangle is for example aligned essentially at right angles to the plane of the printed circuit board. This makes a compact structure the power module possible.

In an embodiment the power module furthermore includes at least one snubber capacitor. The respective snubber capacitor is disposed on the printed circuit board. The respective snubber capacitor is electrically connected to the respective direct current terminal, and wherein the electrical connection between the respective snubber capacitor and the respective direct current terminal is at most twice as long, especially at most exactly the same length or at most half as long as the distance between the two outer direct current terminals.

The respective snubber capacitor likewise contributes to a low-inductance structure of the power module, for which the respective snubber capacitor is disposed very close to the respective direct current terminal and is electrically connected to the terminal. What is more, the respective snubber capacitor is electrically connected to a suitable electrical potential.

In an embodiment the power module is able to be operated with an electrical power of at least several 10s of kilowatts, for example 40 kW to 500 kW, with an alternating current of several 100s of volts, for example 280 V to 800 V, with a direct current of at least several 100s of volts, for example 800 V to 1500 V, and/or electrical currents of several 10s of amperes, for example 70 A to 1000 A.

In an embodiment the power module includes a surface area of 80 cm² to 100 cm². The surface area is especially rectangular, with a length of around 150 mm on its long side and with a length of around 62.5 mm on its short side.

In an embodiment the electrical device includes a base board and at least two of the power modules. The power modules are disposed next to one another on the base board in such a way that the DC terminal sides of power modules point in the same direction, furthermore having a respective device busbar, that is electrically connected to the respective direct current terminal (DCP, DCM, DCN) of the respective power module and optionally to the respective capacitor, and wherein the device busbars are disposed, at least in sections, in parallel to one another.

For example the respective device busbar may be configured in one piece with the respective corresponding busbar of the individual power module. The direct current terminals of the power modules with the same electrical potential may thus be connected to a respective device busbar. The respective corresponding busbar of the individual power module may be part of the corresponding device busbar. By the power modules being disposed in such a way that their respective DC terminal side points in the same direction, comparatively short respective device busbars are made possible, that contributes to a low-inductance structure of the electrical device. This arrangement is achieved for example by the power modules being disposed in a row alongside one another.

As already stated above for the respective power module with regard to the respective busbar, the respective device busbars may be routed for at least half of their length in parallel or equidistant from one another. The deviations explained above may still be acceptable in relation to the device busbars. The parallel or equidistant routing of the device busbars in its turn contributes to a low-inductance structure of the electrical device. For example the device busbars are furthermore disposed in accordance with their electrical potential in ascending order from negative direct current terminal to positive direct current terminal or in descending order from positive direct current terminal to negative direct current terminal.

For example the electrical device includes at least three such power modules, wherein a three-phase alternating current is able to be supplied to the electrical device and the respective power module accommodates one of the three phases of the alternating current.

In the proposed method it is of particular advantage that for example conventional power modules obtainable at low cost, that are especially conceived for 2-level applications, may be used as initial power modules. Such a conventional power module may for example merely have at least one alternating current terminal on the AC terminal side and also two direct current terminals on the DC terminal side. Such conventional power modules are known for example from U.S. Pat. No. 8,847,328B1 already mentioned above, that have four power terminals, for example two alternating current terminals and two direct current terminals lying opposite them. Such a conventional power module may also serve without its own printed circuit board as an initial power module of the proposed method. For example the initial power module may have the housing and for example the available (screw) terminals of the conventional power module.

Such an initial power module is then equipped with the printed circuit board suitable for the power module. The printed circuit board is disposed in such a way that one of the middle direct current terminals and one of the outer direct current terminals are disposed in each case on the DC terminal side and, in a plan view, outside the printed circuit board. The initial power module is furthermore equipped with at least one further direct current terminal, that is disposed in each case between the AC terminal side and the DC terminal side and, in a plan view, is disposed in the region of the printed circuit board or of the respective transistor module.

For example a respective electrical connection of the respective alternating current terminal and of the respective direct current terminal are established with the printed circuit board in addition.

As already mentioned above, the initial power module may especially have the housing and for example the available (screw) terminals of the conventional power module. Then, within the framework of the proposed method, the printed circuit board and also the additional direct current terminal or the additional direct current terminals are provided and attached. For example the arrangement of the transistors or IGBTs is additionally changed or provided as a new arrangement.

Of particular advantage with the power module or electrical device, and especially with the method, is that for example a low-inductance structure may be achieved with the aid of conventional power modules or IGBT modules with screw terminals, without having to massively adapt the module housing of the conventional power module. for example a specific arrangement of the terminal technology for 3-level applications is proposed, that allows a low-inductance structure in existing, conventional module housings. An available 2-level IGBT module housing with just soldered-in or press-in pins disposed differently may serve as a basis for a 3-level application or for a 3-level capable power module for example.

For example the power screw connections are routed out without any changes, but are connected somewhat differently internally. Thus the pins 10 and 11 may furthermore be routed out as alternating current terminals, wherein pin 4 may be routed out as the positive direct current terminal, pin 3 as the middle direct current terminal and the negative direct current terminal via the lateral soldered-in or press-in pins. Via these lateral pins, that are connected to the printed circuit board, the current may be tapped off via a screw terminal mounted on the printed circuit board (for example soldered on or pressed in). Furthermore the positive direct current terminal and the negative direct current terminal may optionally be swapped. For an inductance structure of the power module that is as low as possible the middle direct current terminal is for example disposed in the middle. In this way, through a connection of the initial power module, the printed circuit board and the external screw terminal, a fully-fledged, low-inductance 3-level power module, that may be applied at a minimum cost may be obtained. Various busbar variants may be applied, standing on edge or disposed flat above one another. For applications with more than three DC voltage potentials a corresponding power module or a corresponding production method is proposed.

This specific compact combination includes decisive advantages compared to conventional terminal technology for power modules, for example IGBT modules. For example this application is optimally suited to 3-level applications, but also for applications with 4 or more levels or DC voltage potentials. for example a low-inductance terminal technology is achieved for the power module. Furthermore the power module or method provides existing IGBT module housings or initial power modules to be reused. A compact terminal technology is used that does not exceed the IGBT module housing or need more installation space than the IGBT module housing or the initial power module. The method is especially suitable for low volumes, since no investment is required in new 3-level housings. This also applies equally to universal housings with optional plug-in soldered-in or press-in pins. What is more, further components, such as for example snubbers, may be disposed close to the IGBT or direct current terminals. The proposed structure of the power module is very compact compared with alternative solutions and for example only occupies 93.8 cm² of surface area. This comparatively small surface area may be decisive for use in compact frequency converters.

### BRIEF DESCRIPTION OF THE FIGURES

FIGS. 1-8 depict embodiments of the power module.

FIG. 9 depicts an embodiment of the electrical device.

FIG. 10 depicts a flow diagram of an embodiment of the method for producing an embodiment of a power module.

### DETAILED DESCRIPTION

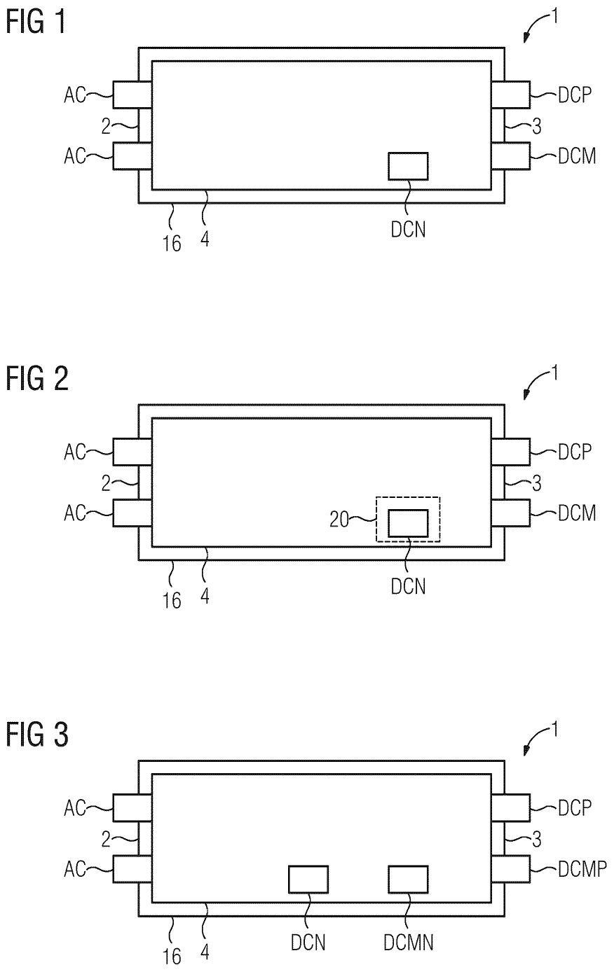

FIG. 1 depicts a first embodiment of the power module 1, wherein a schematic view is shown.

The power module 1 includes an AC terminal side 2 and a DC terminal side 3 lying opposite the AC terminal side 2 as well as a printed circuit board 4. The power module furthermore includes two alternating current terminals AC disposed on the AC terminal side 2 and also three direct current terminals DCP, DCM, DCN. Of the three direct current terminals DCP, DCM, DCN, the middle direct current terminal DCM and also the positive direct current terminal DCP are disposed on the DC terminal side 3, and, in a plan view, outside the printed circuit board 4. The third of the three direct current terminals DCP, DCM, DCN is the negative direct current terminal DCN, that is disposed between the AC terminal side 2 and the DC terminal side 3, and, in a plan view, in the region of the printed circuit board 4. the positive direct current terminal DCP and the negative direct current terminal DCN form the two outer direct current terminals DCP, DCN.

The two alternating current terminals AC and the two direct current terminals disposed on the DC terminal side, for example the middle direct current terminal DCM and also the positive direct current terminal DCP, are essentially in the plane of the printed circuit board 4 and are disposed as an extension of the printed circuit board 4 to the AC terminal side 2 or to the DC terminal side 3. The negative direct current terminal DCN on the other hand is disposed above the printed circuit board 4 and between the AC terminal side 2 and the DC terminal side 3.

The power module furthermore includes a housing 16, that houses the printed circuit board 4 at least partly.

For example, as shown in FIG. 1, the middle direct current terminal DCM is disposed between the positive direct current terminal DCP and the negative direct current terminal DCN. For example the direct current terminals DCP, DCM, DCN are each disposed essentially equidistant from one another.

The power module 1 shown in FIG. 1 includes exactly three direct current terminals DCP, DCM, DCN in this case, so that 3-level applications are able to be realized with the module.

FIG. 2 depicts a second embodiment of the power module 1, wherein once again a schematic view is shown. The same reference numbers as in FIG. 1 refer to the same objects in this figure. Since the second embodiment includes a few similarities with the first embodiment, a few differences will be explained below.

The power module furthermore includes a transistor module 20 that, in a plan view of the printed circuit board 4, is disposed behind the printed circuit board 4. Thus first of all the direct current terminal DCN, then the printed circuit board 4 and then the transistor module 20 are disposed in a plan view of the power module 1. The direct current terminal DCN is disposed between the AC terminal side 2 and the DC terminal side 3 and, in a plan view, in the region of the transistor module 20 of the power module 1.

Such a transistor module 20 may for example also be provided in each case in the remaining embodiments of the power module 1. The respective remaining direct current terminal is then disposed between the AC terminal side 2 and the DC terminal side 3 and, in a plan view, in the region of the (respective) transistor module 20 of the power module 1.

FIG. 3 depicts a third embodiment of the power module 1, wherein once again a plan view is shown. Since the third embodiment includes a few similarities with the first embodiment, a few differences will be explained below.

The power module 1 shown in FIG. 3 includes four direct current terminals DCP, DCMP, DCMN, DCN, for example the positive direct current terminal DCP, now however two middle direct current terminals DCMP and DCMN and the negative direct current terminal DCN. For example the four direct current terminals DCP, DCMP, DCMN, DCN are configured for corresponding electrical potentials, that are essentially equidistant from one another, so that the potential difference between the pairs of direct current terminals DCP-DCMP, DCMP-DCMN, and DCMN-DCN is essentially the same. As shown in FIG. 3, in this power module 1 the positive direct current terminal and the middle direct current terminal DCMP are disposed on the DC terminal side 3. The negative direct current terminal DCN and also the middle direct current terminal DCMN are disposed between the AC terminal side 2 and the DC terminal side 3 and, in a plan view, in the region of the printed circuit board 4. 4-level applications are able to be realized with the four direct current terminals DCP, DCMP, DCMN, DCN.

For example as is shown in FIG. 3, the two middle direct current terminals DCMP, DCMN are disposed between the positive direct current terminal DCP and the negative direct current terminal DCN. the four direct current terminals DCP, DCMP, DCMN, DCN from the positive direct current terminal DCP towards the negative direct current terminal DCN are disposed in accordance with their respective electrical potential provided in descending order from positive direct current terminal DCP to negative direct current terminal DCM. For example the direct current terminals DCP, DCMP, DCMN, DCN are each disposed essentially equidistant from one another.

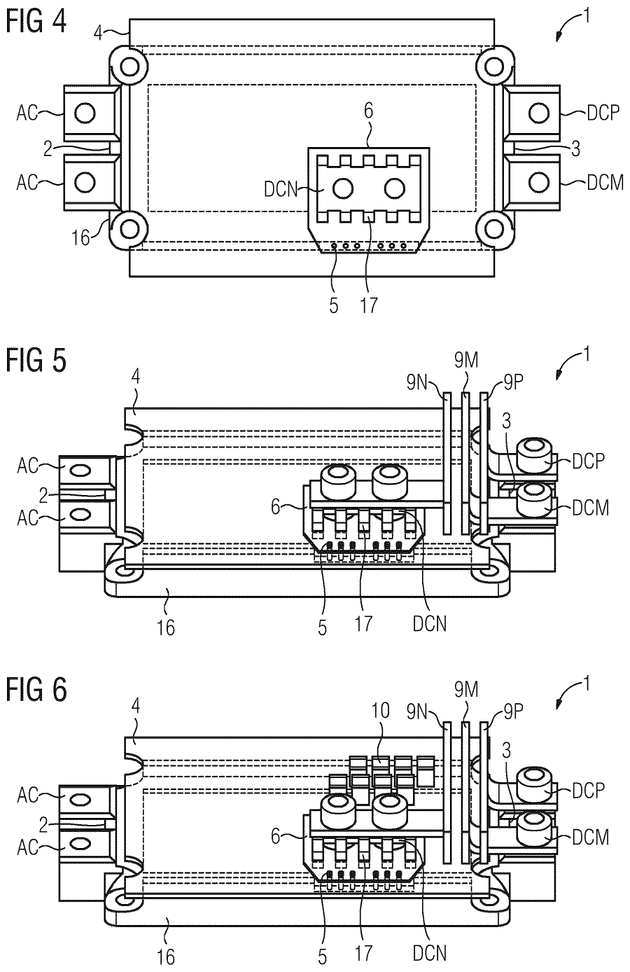

FIG. 4 depicts a fourth embodiment of the power module 1, wherein once again a plan view is shown. Since the fourth embodiment includes a few similarities with the first embodiment, a few differences will be explained below.

The printed circuit board 4, between the AC terminal side 2 and the DC terminal side 3, includes a number of terminal pins 5 protruding from the printed circuit board 4, that for example may be terminal pins of a transistor or transistor module 20 not shown in any greater detail, that may be disposed on the printed circuit board 4 or on the rear side of the printed circuit board 4. the negative direct current terminal DCN is electrically connected to the terminal pins 5 via a connection 17 and also a conductor surface 6. The conductor surface 6 may be configured for example as a DCB and for example be disposed in parallel to the printed circuit board 4. For example the printed circuit board 4 completely covers the conductor surface 6 in a plan view, i.e. as shown for example in FIG. 4.

FIG. 5 depicts a fifth embodiment of the power module 1, wherein a perspective and schematic view of the power module 1 is shown. Since the fifth embodiment includes a few similarities with the fourth embodiment, a few differences will be explained below.

The power module 1 furthermore includes three busbars 9N, 9M and 9P, that are electrically connected to the respective direct current terminal DCP, DCM and DCN. As indicated in FIG. 5, the three busbars 9N, 9M, 9P are essentially disposed in parallel to and equidistant from one another. the busbar 9M of the middle electrical potential is disposed between the busbars 9P and 9N of the positive and negative electrical potentials disposed. Furthermore the three busbars 9N, 9M and 9P each have a rectangular cross section. The long side of the respective rectangle stands at right angles to the plane of the printed circuit board 4.

FIG. 6 depicts a sixth embodiment of the power module 1, wherein once again a perspective and schematic view of the power module 1 is shown. Since the sixth embodiment includes a few similarities with the fifth embodiment, a few differences will be explained below.

The power module 1 furthermore includes a number of snubber capacitors 10, that are disposed on the printed circuit board 4 and are suitably electrically connected to the respective direct current terminal DCP, DCM, DCN. For example the electrical connection between the respective snubber capacitor 10 and the respective direct current terminal DCP, DCM, DCN is at most twice as long, especially at most exactly the same length or at most half as long as the distance between the two outer direct current terminals DCP, DCN.

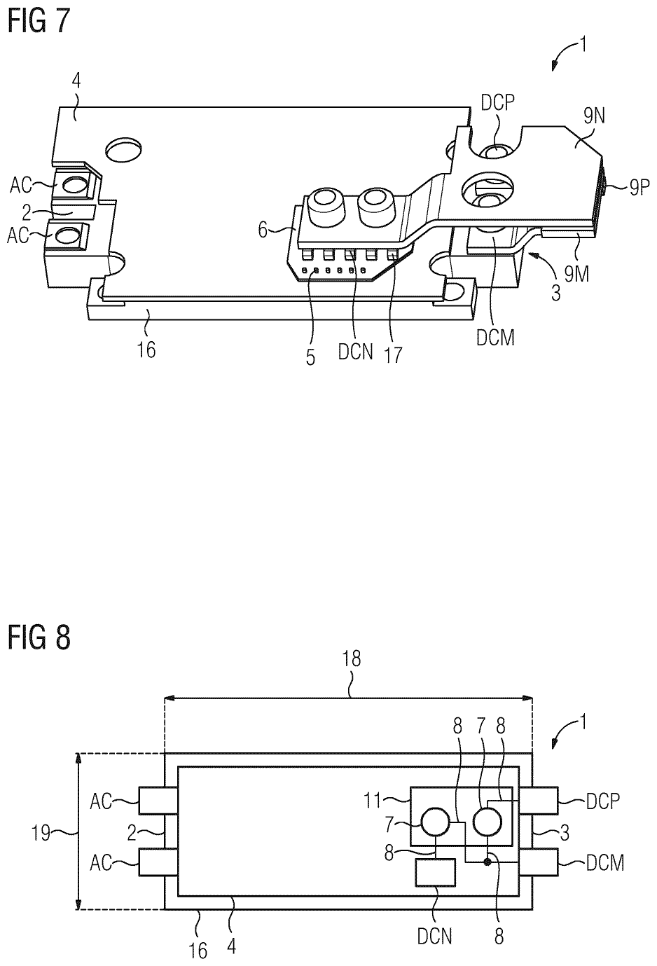

FIG. 7 depicts a seventh embodiment of the power module 1, wherein a perspective and schematic view of the power module 1 is shown. Since the seventh embodiment likewise includes a few similarities with the fifth embodiment, a few differences will be explained below.

The three busbars 9N, 9M and 9P once again have a rectangular cross section, wherein now however the short side of the respective rectangle stands at right angles to the plane of the printed circuit board 4. The flat busbars 9N, 9M and 9P are thus disposed in parallel to the plane of the printed circuit board 4.

FIG. 8 depicts an eighth embodiment of the power module 1, wherein once again a schematic view is shown. Since the eighth embodiment likewise includes a few similarities with the first embodiment, a few differences will be explained below.

The power module 1 includes two capacitors 7, of which the one capacitor 7 is electrically connected to the positive direct current terminal DCP and to the middle direct current terminal DCM via an electrical connection 8 and of which the other capacitor 7 is electrically connected to the middle direct current terminal DCM and to the negative direct current terminal DCN via a further electrical connection 8. the respective electrical connection 8 between the respective capacitor 7 and the respective direct current terminal DCP, DCM, DCN is at most twice as long, especially at most exactly the same length or at most half as long as the distance between the two outer direct current terminals DCP, DCN.

The power module 1 furthermore includes a capacitor board 11, on which the capacitors 7 are disposed. The capacitor board 11 is for example disposed in parallel to the printed circuit board 4. The capacitors 7 on the capacitor board 11 are especially disposed within a rectangle that, in a plan view, is delimited by the direct current terminals DCN, DCM, DCP and that is aligned in parallel to the printed circuit board 4.

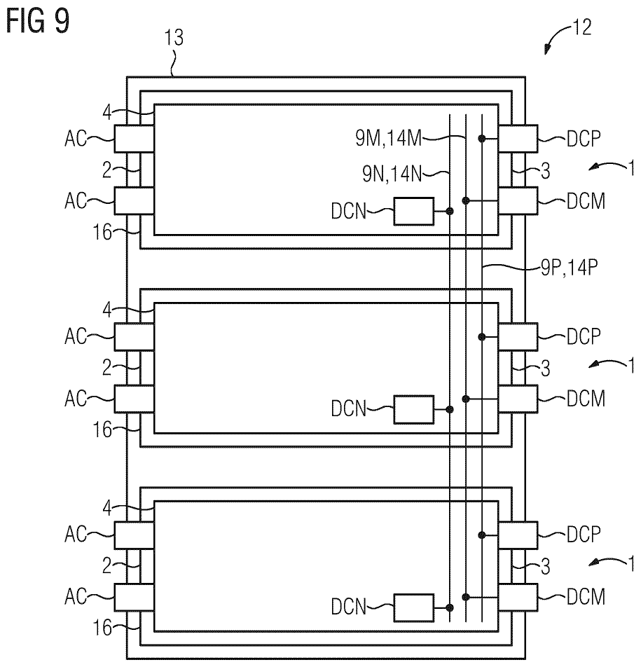

FIG. 9 depicts an embodiment of the proposed electrical device 12, wherein a schematic view is shown.

The electrical device 12 includes a base board 13 on which three power modules 1 are disposed. The three power modules 1 may especially be configured in accordance with one of the embodiments above. The three power modules 1 are disposed next to one another and are aligned so that their respective DC terminal side 3 points in the same direction, to the right in FIG. 9. The electrical device 12 furthermore includes three device busbars 14P, 14M and 14N, that are electrically connected to the respective direct current terminal DCP, DCM and DCN of respective power modules 1. For example the respective power module 1 may have three busbars 9P, 9M and 9N in each case, as explained in embodiments 4 and 5. The busbars 9P, 9M and 9N of the respective power module 1 may be configured in one piece with the three device busbars 14P, 14M and 14N, as shown in FIG. 9.

Furthermore, as indicated in FIG. 9, the three device busbars 14P, 14M and 14N are essentially disposed in parallel to and equidistant from one another. the device busbar 14M of the middle electrical potential is disposed between the device busbars 14P and 14N of the positive and negative electrical potentials. The three device busbars 14P, 14M and 14N may each have a rectangular cross section. The long or the short side of the respective rectangle stands at right angles to the plane of the printed circuit board 4.

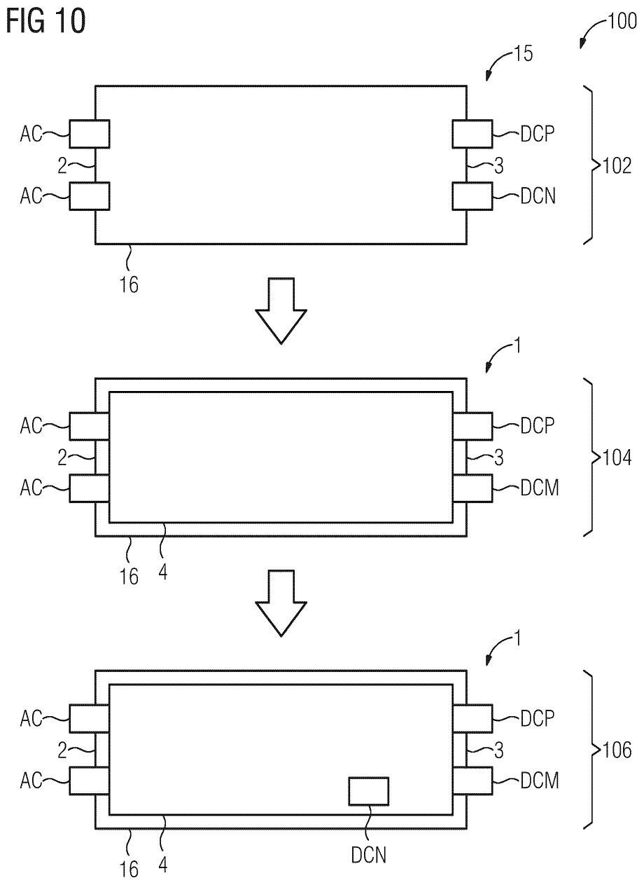

FIG. 10 depicts a flow diagram of an embodiment of the proposed method 100 for production of an embodiment of a power module 1.

In a first step 102, an initial power module 15 having two alternating current terminals AC disposed on the AC terminal side 2 and two direct current terminals DCP, DCN disposed on the DC terminal side 3 is provided. The initial power module 15 furthermore includes a housing 16, that holds the alternating current terminals AC and the direct current terminals DCP, DCN. As already mentioned further above, such an initial power module 15 may be a conventional power module for example, that is known for example from U.S. Pat. No. 8,847,328B1 hereby incorporated by reference in its entirety.

In a second step 104, a suitable printed circuit board 4 is provided and disposed between the AC terminal side 2 and the DC terminal side 3. the middle direct current terminal DCM and the positive direct current terminal DCP are disposed on the DC terminal side 3 and, in a plan view, outside the printed circuit board 4. For example the function of the negative direct current terminal DCN of the initial power module 15 is changed to the middle direct current terminal DCM of the power module 1.

In a third step 106, the negative direct current terminal DCN is provided between the AC terminal side 2 and the DC terminal side 3 and, in a plan view, in the region of the printed circuit board 4.

For example in addition, for example in a further step, a respective electrical connection of the alternating current terminals AC and of the respective direct current terminal DCP, DCM, DCN is established with the printed circuit board 4.

It is to be understood that the elements and features recited in the appended claims may be combined in different ways to produce new claims that likewise fall within the scope of the present embodiments. Thus, whereas the dependent claims appended below depend from only a single independent or dependent claim, it is to be understood that these dependent claims may, alternatively, be made to depend in the alternative from any preceding or following claim, whether independent or dependent, and that such new combinations are to be understood as forming a part of the present specification.

While the present embodiments have been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A power module comprising:
an AC terminal side; and
a DC terminal side lying opposite the AC terminal side;
a printed circuit board;
at least one alternating current terminal disposed on the AC terminal side; and
at least three direct current terminals comprising one or more middle direct current terminals and two outer direct current terminals comprising a positive direct current terminal and a negative direct current terminal;
wherein one of the middle direct current terminals and one of the outer direct current terminals are disposed on the DC terminal side and, in a plan view, are disposed outside of the printed circuit board; and
wherein a respective remainder of the direct current terminals are disposed between the AC terminal side and the DC terminal side and, in a plan view, in a region of the printed circuit board.

2. The power module of claim 1, wherein a respective middle direct current terminal is disposed between the positive direct current terminal and the negative direct current terminal.

3. The power module of claim 1,
wherein the printed circuit board has at least one terminal pin protruding from the printed circuit board between the AC terminal side and the DC terminal side, and wherein a respective remaining terminal of the direct current terminals is electrically connected to the respective terminal pin.

4. The power module of claim 3, further comprising a respective conductor surface, wherein the respective conductor surface is disposed between the respective terminal pin and the respective remaining terminal of the direct current terminals, and wherein the respective terminal pin and the respective remaining terminal of the direct current terminals is electrically connected to the respective conductor surface.

5. The power module of as claim 4, wherein the respective conductor surface is disposed parallel to the printed circuit board, and/or wherein the printed circuit board, in a plan view, completely covers the respective conductor surface.

6. The power module of claim 1, further comprising:
at least two capacitors, wherein one of the capacitors of the at least two capacitors is electrically connected to one of the outer direct current terminals and to one of the middle direct current terminals and wherein another of the capacitors of the at least two capacitors is electrically connected to the other of the outer direct current terminals and to one of the middle direct current terminals, and
wherein the electrical connection between the respective capacitor and a respective direct current terminal is at most twice as long, as a distance between the two outer direct current terminals.

7. The power module of claim 1, further comprising a respective busbar, which is electrically connected to a respective direct current terminal
wherein busbars are at least predominantly disposed in parallel to one another, and wherein the respective busbar of a respective middle direct current terminal is disposed between the busbars of the two outer direct current terminals.

8. The power module of claim 1, further comprising:
at least one snubber capacitor, wherein a respective snubber capacitor is disposed on the printed circuit board, wherein the respective snubber capacitor is electrically connected to a respective direct current terminal, and wherein the electrical connection between the respective snubber capacitor and the respective direct current terminal is at most twice as long as a distance between the two outer direct current terminals.

9. The power module of claim 1, wherein the power module is operated with an electrical power of at least several 10s of kilowatts with an alternating current of at least several 100s of volts, with a direct current of at least several 100s of volts, and/or electrical currents of several 10s of amperes.

10. The power module of claim 1, wherein the power module has a surface area of 80 cm² to 100 cm2, wherein the surface area is rectangular with a length of 150 mm on its long side and with a length of 62.5 mm on its short side.

11. (canceled)

12. An electrical device comprising:
a base board; and
at least two power modules, each power module of the at least two power modules comprising:
an AC terminal side;
a DC terminal side lying opposite the AC terminal side;
a printed circuit board;
at least one alternating current terminal disposed on the AC terminal side; and
at least three direct current terminals comprising one or more middle direct current terminals and two outer direct current terminals comprising a positive direct current terminal and a negative direct current terminal;
wherein one of the middle direct current terminals and one of the outer direct current terminals are disposed on the DC terminal side and, in a plan view, are disposed outside of the printed circuit board; and
wherein a respective remainder of the direct current terminals are disposed between the AC terminal side and the DC terminal side and, in a plan view, in a region of the printed circuit board;
wherein the at least two power modules are disposed alongside one another on the base board disposed in such a way that the DC terminal sides of the at least two power modules point in the same direction, and
a respective device busbar, which is electrically connected to the respective direct current terminal of a respective power module and optionally to a respective capacitor (7), and wherein the device busbars are disposed, at least in sections, parallel to one another.

13. A method for producing a power module, the method comprising:
configuring an initial power module comprising: at least one alternating current terminal disposed on an AC terminal side and
two direct current terminals disposed on a DC terminal side;
configuring a printed circuit board between the AC terminal side and the DC terminal side in such a way that one of the middle direct current terminals and one of an outer direct current terminals are disposed in each case on the DC terminal side and, in a plan view, are disposed outside the printed circuit board, and
configuring at least one further direct current terminal between the AC terminal side and the DC terminal side and, in a plan view, in a region of the printed circuit board.
